(19) United States
(12) Patent Application Publication
(10) Pub. No.: US 2025/0336854 A1
(43) Pub. Date: Oct. 30, 2025

(54) PROTRUDED BOND PADS FOR HYBRID BONDING OF SEMICONDUCTOR DEVICES

(71) Applicant: Micron Technology, Inc., Boise, ID (US)

(72) Inventors: Terrence B. McDaniel, Boise, ID (US); Vinay Nair, Boise, ID (US); Yi Fang Lee, Boise, ID (US); Eiichi Nakano, Boise, ID (US)

(21) Appl. No.: 19/193,773

(22) Filed: Apr. 29, 2025

Related U.S. Application Data
(60) Provisional application No. 63/640,819, filed on Apr. 30, 2024.

(51) Int. Cl. H01L 23/00; H01L 25/18; H10B 80/00; H10D 80/30

(52) U.S. Cl. CPC H01L 24/05; H01L 24/03; H01L 24/08; H01L 24/80; H01L 25/18; H10B 80/00; H10D 80/30; H01L 2224/03009; H01L 2224/0345; H01L 2224/03848; H01L 2224/05022; H01L 2224/05025; H01L 2224/05073; H01L 2224/05109; H01L 2224/05111; H01L 2224/05124; H01L 2224/05139; H01L 2224/05144; H01L 2224/05147; H01L 2224/05155; H01L 2224/05164; H01L 2224/05166; H01L 2224/05169; H01L 2224/05556; H01L 2224/05562; H01L 2224/05568; H01L 2224/05582; H01L 2224/05609; H01L 2224/05611; H01L 2224/05624; H01L 2224/05639; H01L 2224/05644; H01L 2224/05647; H01L 2224/05655; H01L 2224/05664; H01L 2224/05666; H01L 2224/05669; H01L 2224/08059; H01L 2224/0807; H01L 2224/08148; H01L 2224/80203; H01L 2224/80895; H01L 2224/80896; H01L 2924/30101; H01L 2924/351; H01L 2924/37001

(57) ABSTRACT

A semiconductor device assembly including a first semiconductor die having a first dielectric region and a first bond pad that are disposed on a first side of the first semiconductor die, and a second semiconductor die having a second dielectric region and a second bond pad that are disposed on a second side of the second semiconductor die, wherein a hybrid bonding interface between the first side of the first semiconductor die and the second side of the second semiconductor die includes a conductive region between the first bond pad and the second bond pad, and wherein the conductive region and at least one of the first and the second bond pads include a same conductive material element, and the conductive region has an electrical resistivity lower than the at least one of the first and the second bond pads.

### CROSS-REFERENCE TO RELATED APPLICATION(S)

The present application claims priority to U.S. Provisional Patent Application No. 63/640,819, filed Apr. 30, 2024, the disclosure of which is incorporated herein by reference in its entirety.

### TECHNICAL FIELD

The present disclosure generally relates to semiconductor devices, and more particularly relates to hybrid bonding for semiconductor device assemblies.

### BACKGROUND

Semiconductor packages typically include a semiconductor die (e.g., memory chip, microprocessor chip, imager chip) mounted on a substrate or a semiconductor wafer and encased in a protective covering (e.g., an encapsulating material). The process of attaching semiconductor dies on a semiconductor wafer in general refers as chips on wafer (CoW) process, which can increase throughput and reduce difficulties in handling individual semiconductor dies as they continue to shrink in size. Individual semiconductor dies can further be stacked in the semiconductor assemblies. Similar challenges exist in semiconductor wafer-on-wafer (WoW) bonding process. Hybrid bonding (also refers as fusion bonding or direct bonding) provides a bonding process with minimal intermediate layers between semiconductor dies and semiconductor wafer in the CoW and WoW processes. The hybrid bonding technique helps semiconductor manufacturers meet demands for a reduction in the volume occupied by semiconductor die and semiconductor wafer assemblies.

### BRIEF DESCRIPTION OF THE DRAWINGS

FIG. 1 depicts a cross section view of semiconductor dies that are boned together in accordance with embodiments of the present technology;

FIGS. 2A through 2F illustrate stages of processing a semiconductor die having protruded conductive regions above its frontside surface in accordance with embodiments of the present technology;

FIGS. 3A and 3B illustrate stages of hybrid bonding of two semiconductor dies having protruded conductive regions in accordance with embodiments of the present technology;

FIGS. 4A and 4B illustrate stages of hybrid bonding a semiconductor die having protruded conductive regions and another semiconductor die without protruded conductive regions in accordance with embodiments of the present technology;

FIG. 5 is a flow chart illustrating a method of processing semiconductor device assembly according to embodiments of the present technology;

FIG. 6 is a flow chart illustrating a method of forming protruded conductive regions above a frontside surface of a semiconductor die according to embodiments of the present technology; and

FIG. 7 is a schematic view of a system that includes a semiconductor device configured according to embodiments of the presented technology;

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the drawings, the same reference numerals used in different embodiments designate like or corresponding, but not necessarily identical, elements.

### DETAILED DESCRIPTION

Hybrid bonding process offers significant advantages in semiconductor device assembly for high-performance integrated circuits (ICs) and advanced memory technologies. For example, hybrid bonding process allows direct bonding of die to die or die to wafer interfaces at a finer pitch in comparison to traditional solder bump interconnections. The high density interconnection of hybrid bonding enables more connections per unit area and facilitates integration of more functions into a single semiconductor device assembly. In addition, a direct metal-metal bonding of the hybrid bonding can reduce the interconnection length and eliminate a need for underfill materials, achieving a lower contact resistance and capacitance. The resulted semiconductor device assembly can provide faster electrical signal transmission with reduced power consumption. However, forming a reliable metal-metal bonds during the hybrid bonding process in semiconductor device assembly presents several challenges that affect ensuring high yield and good performance of the final device. For example, high precision of alignment and placement of the bond pads is critical for metal-to-metal bonding in the hybrid bonding, as any misalignment can lead to poor electrical connections and reduced device performance. In semiconductor device assembly, achieving sub-micron accuracy in alignment can be challenging, particularly for large volume manufacturing of semiconductor devices. Further, the differences in the thermal expansion coefficients of the bond pad materials and adjacent dielectric materials involved in the hybrid bonding process can induce mechanical stress on the bonding interface, causing bond failure or device degradation.

To address these challenges and others, the present technology applies bond pad material protrusion from an incident semiconductor wafer surface into the hybrid bonding process, to enable better device yielding and a lower resistance metal-metal bond contact interface. In particular, the present technology amorphizes a frontside surface region of bond pad materials using high energy beam implantation of inert ions. The injected inert ions degrade the crystallinity of original bond pad material and make it amorphous. After that, a thermal anneal process is conducted to form protruded bond pads regions from the amorphous bond pads. The protruded bond pads expand along a frontside surface of the semiconductor die, in a mushroom shape and with a recrystallized crystal structure. The protruded bond pads also have lower electrical conductivity to original bond pads due to the recrystallization thermal anneal process. During the hybrid bonding process, bond pads of opposing semiconductor dies can be aligned and bonded, through the protruded bond pads. Because the protruded bond pads have a larger diameter and lower electrical resistivity to the bond pads, the present technology enables an easily bond pads alignment and faster electrical signals run path between the hybrid bonded semiconductor dies. The present technology is applicable in the CoW bonding process. For example, the protruded bond pads structure can exist in a semiconductor die or a semiconductor wafer in assisting the CoW bonding process. Alternatively, the present technology can be applied in a WoW bonding process. For example, conducting a hybrid bonding process on semiconductor wafers having the protruded bond pads structure at the bonding interface.

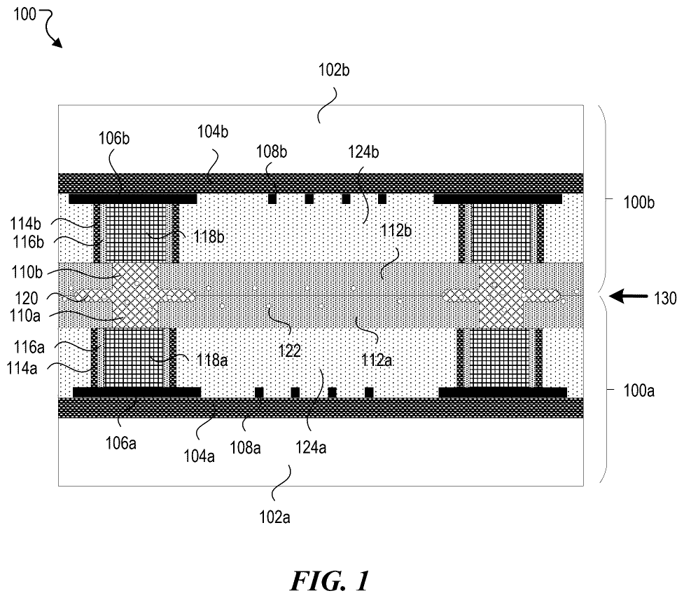

FIG. 1 shows a cross section view of a semiconductor die assembly 100, in which semiconductor dies 100a and 100b are bonded to each other in accordance with embodiments of the present technology. The semiconductor die 100a includes a substrate 102a having a frontside and a backside opposite to the frontside. The frontside of the substrate 102a may include integrated circuits (e.g., a memory array, peripheral circuitry operatively coupled to the memory array, etc.). The substrate 102 may be made of materials including silicon, silicon germanium, glass, or any combination thereof. In addition, the semiconductor die 100a includes a back-end-of-line (BEOL) structure 104a, probe pads 106a, conductive lines 108a, and vias 118a formed above the frontside of the substrate 102. In some embodiments, the BEOL structure 104a including metallization layers and dielectric isolation layers can be fabricated on the substrate 102a. The BEOL structure 104 may include metallic materials (e.g., copper and/or aluminum) and dielectric materials (e.g., silicon oxide, and/or silicon nitride). Individual devices such as transistors, capacitors, and/or resistors disposed on the frontside of the substrate 102a can be interconnected through the BEOL structure 104a and further electrically connected with 1/O of the semiconductor die 100a.

The semiconductor die 100a further includes a dielectric layer 124a that is formed above the BEOL structure 104a and that encapsulates the probe pads 106a and the plurality of conductive lines 108a. The dielectric layer 124a may have a thickness ranging from 1 μm to 5 μm and be made of materials including tetraethyl orthosilicate (TEOS), silicon oxide (SiO), silicon nitride (SiN), silicon borocarbonitride (SiBCN), silison oxycarbonitride (SiOCN), silicon oxycarbide (SiOC), silicon carbonitride (SiCN), silicon boronitride (SiBN), a low-k dielectric material, or a combination thereof. Moreover, a dielectric layer 112a may be formed on the dielectric layer 124a. The dielectric layer 112a may be deposited at a high temperature around 350° C. and made of materials such as silicon oxide, silicon nitride, silicon carbon nitride (SiCN), silicon boron carbonitride (SiBCN), or any combination thereof. In addition, the dielectric layer 112a may have a thickness ranging from 10 nm to 500 nm.

As shown in FIG. 1, each of the vias 118a is disposed above corresponding probe pads 106a and are isolated from the dielectric layer 124a by multiple liner material layers 114a and 116a. The multiple liner material layer 114a can be adhesive materials that are used to improve the adhesion between via materials and the dielectric layer 124a. In addition, the layer 116a can be a barrier layer configured to prevent the diffusion of via material into the surrounding dielectric layer 124a. In this example, the via 118a can be made of electrically conductive materials such as copper, aluminum, gold, silver, nickel, platinum, palladium, tin, indium, titanium, or their alloys. The vias 118a are essential conductive pathways that allow for signal and power to be transmitted across various layers within the semiconductor die 100a or between the semiconductor die 100a and external environment such as semiconductor die 100b. In this example, each of the vias 118a can have a thickness close to the dielectric layer 124a, ranging from 1 μm to 5 μm. Moreover, each of the vias 118a can have a circular shape or a rectangular shape, having a diameter ranging from 100 nm to 5 μm.

The semiconductor die 100a also includes bond pads 110a that is deposited above corresponding vias 118a and isolated/surrounded by the dielectric layer 112a therebetween. The bond pads 110a can be made of electrically conductive materials such as copper, aluminum, gold, silver, nickel, platinum, palladium, tin, indium, titanium, or their alloys. In addition, each of the bond pads 110a can have a thickness ranging from 1 nm to 100 μm. As shown in FIG. 1, the diameter of each of the bond pads 110a is smaller than corresponding via 118a, ranging from 50 nm to 5 μm. In this example, the one of the bond pads 110a can be electrically coupled to the corresponding probe pads 106a through corresponding via 118a.

The semiconductor die 100b may have a same configuration to the semiconductor die 100a. For example, the semiconductor die 100b includes a substrate 102b having a frontside surface and a backside surface. BEOL structure 104b can be disposed above the frontside surface of the substrate 102b. In addition, the semiconductor die 100b includes probe pads 106b, conductive lines 108b, and vias 118b formed above the BEOL structure 104b. Similar to the semiconductor die 100a, the vias 118b can be coated by adhesive material 114b and barrier layer 116b. As shown in FIG. 1, the vias 118b can be isolated by a dielectric layer 124b. Another dielectric layer 112b can be formed above the dielectric layer 124b. Moreover, the semiconductor die 100b can include bond pads 110b each being disposed above corresponding via 118b. In this example, the dimension and material of corresponding components of the semiconductor dies 100a and 100b can be similar or identical. In some other examples, the materials of corresponding components of the semiconductor dies 100a and 100b may vary. For example, the thicknesses of dielectric layers 112a and 112b may be different. In addition, the thickness and diameter of bond pads 110a and 110b may be different.

In this example, the semiconductor die assembly 100 reveals a chip to chip (C2C) assembly and a frontside to frontside (F2F) direct bonding scheme. For example, as shown in FIG. 1, the semiconductor die 100a is attached to the semiconductor die 100b through a hybrid bonding at a bonding interface 130. It can be found that the semiconductor die 100b is flipped upside down for the device assembly. As shown, the frontside surface of the semiconductor die 100a is bonded with the frontside surface of the semiconductor die 100b. In particular, the hybrid bonding included in the semiconductor die assembly 100 includes dielectric-dielectric bonds between the dielectric layer 112a of the semiconductor die 100a and the dielectric layer 112b of the semiconductor die 100b, and metal-metal bonds between the bond pads 110a of the semiconductor die 100a and the bond pads 110b of the semiconductor die 100b.

Particularly, the metal-metal bonds included in the semiconductor die assembly 100 includes conductive regions 120 at the hybrid bonding interface 130. As shown in FIG. 1, each of the conductive regions 120 is disposed between corresponding bond pads 110a and 110b. The conductive region 120 includes a same electrically conductive material to the adjacent bond pads, such as copper. It can be found that the conductive regions 120 each has a larger diameter than at least one of adjacent bond pads. For example, each of the conductive regions 120 may have a diameter ranging from 70 nm to 20 μm. Moreover, each of the conductive regions 120 may have a thickness ranging from 1 A to 5 μm. Here, the conductive regions 120 may be polycrystalline and have a larger averaged grain size and a lower density of grain boundaries than at least one of the corresponding bond pads 110a and 110b. Specifically, the conductive regions 120 may have grain sizes in the range of 100 nm to 1 μm. In this example, each of the conductive regions 120 may have a volume up to 50% of that of the bond pad 110a or bond pad 110b.

In this example, each of the conductive regions 120 may have an electrical resistivity similar to or lower than corresponding bond pads 110a and 110b. For example, the conductive regions 120 may include copper and have a resistivity close to or lower than 1.7×10⁻⁸ Ω·m at room temperature. In contrast, the corresponding bond pads 110a or 110b can be made of copper and have a resistivity close to or higher than 1.7×10⁻⁸ Ω·m. In this example, the bond pads 110a and 110b are cojoined through corresponding conductive regions 120 at the metal-metal bonding interface. It can be found that the conductive regions 120 may enhance the device performance of the semiconductor die assembly 100 because it provides a lower resistance path for signal or power transition between the semiconductor dies 100a and 100b. In some examples, there may be voids or gaps exist at the horizontal ends of the conductive region 120 at the bonding interface 130.

In some examples, the conductive regions 120 may be connected to each other, along the bonding interface 130 of the semiconductor die assembly 100. For example, in regions where the pitch of bond pad is narrower than remaining regions of the semiconductor die assembly 100, adjacent conductive regions 120 can be merged and disposed continuously between adjacent bond pads 110a or 110b.

As shown in FIG. 1, the semiconductor die assembly 100 also includes inert ions at the hybrid bonding interface 130. For example, inert ions can exist in the conductive regions 120 and a portion of the bond pads 110a and 110b that are close to the conductive regions 120. In addition, inert ions can be disposed in the dielectric layers 112a and 112b and close to the bonding interface 130. Here, the inert ions can be made of ions including Ar ion, Helium ion, Neon ion, Krypton ion, and/or Xenon ion. The doping level of inert ions ranges from 1×10¹⁴ ions/cm² to 1×10¹⁶ ions/cm². In some other examples, the doping level of inert ions ranges from 1×10¹² ions/cm² to 1×10¹⁴ ions/cm². In some other examples, the doping level of inert ions ranges from 1×10¹⁰ ions/cm² to 1×10¹² ions/cm². Further, the doping level of inert ions may be different between the conductive region 120 and adjacent bond pads 110b and 110b and between the conductive region 120 and the dielectric layers 112a and 112b. Moreover, the doping level of inert ions may be higher when it is closer to the bonding interface 130.

In some other examples, the semiconductor die assembly 100 may reveal a chip to wafer (C2W) assembly. For example, a frontside surface of the semiconductor die 100b can be bonded to a frontside surface of a semiconductor wafer 100a′. In this example, the semiconductor die 100b is attached to the semiconductor wafer 100a′ through the C2W bonding at the bonding interface 130, which includes metal-metal bonding through the bond pads 110a and 110b and the conductive regions 120, as well as dielectric-dielectric bonding between the dielectric layers 112a and 112b.

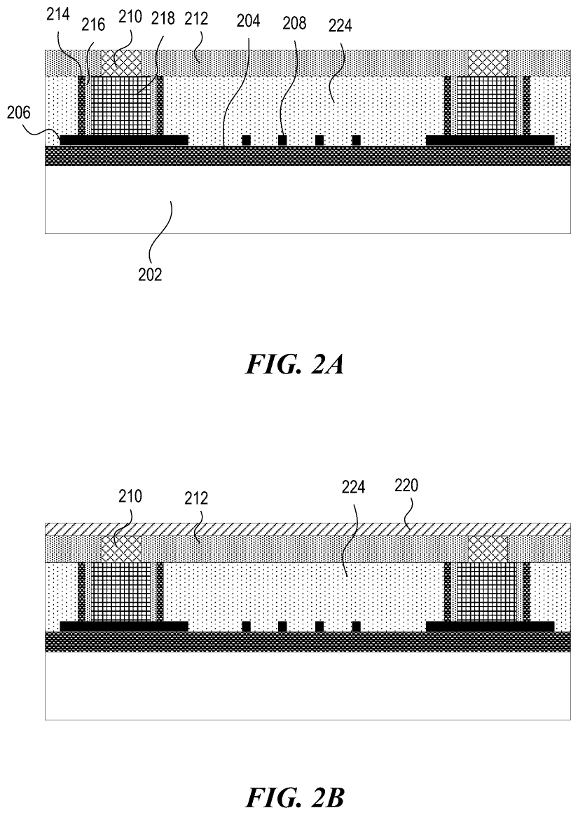

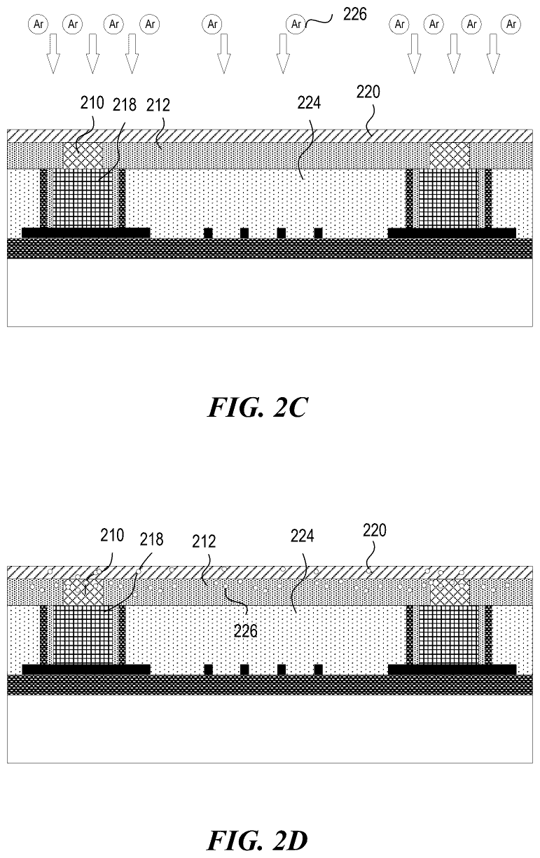

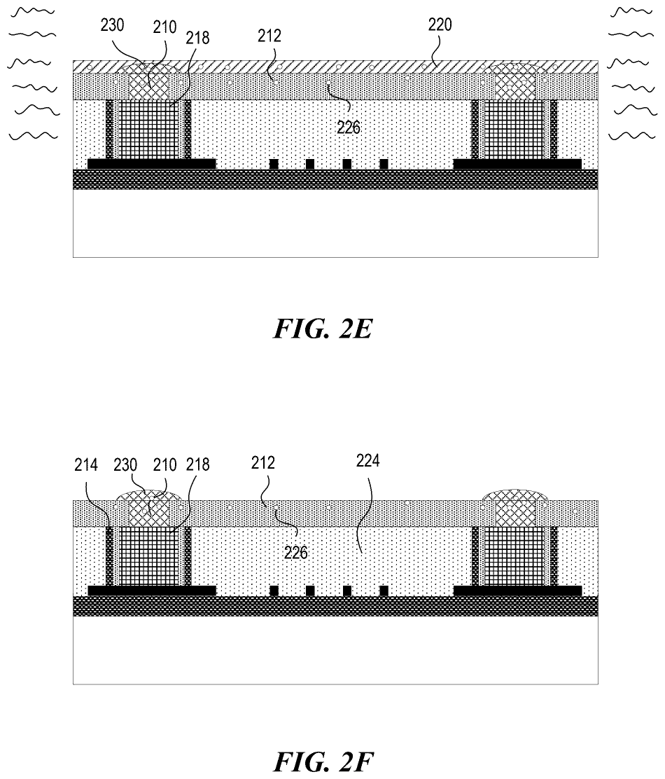

FIGS. 2A through 2E illustrate stages of processing a semiconductor die 200 having protruded conductive regions above its frontside surface in accordance with embodiments of the present technology. FIG. 2A illustrate a cross-sectional view of a substrate 202 provided for various processes upon completing the semiconductor die 200. For example, FIG. 2A shows the substrate 102 having a frontside and integrated circuits formed thereon. BEOL structure 204 can be further formed above the substrate 102. In addition, a plurality of conductive lines 208 and probe pads 206 can be fabricated above the BEOL structure 204. Above each of the probe pads 206, there is a via 218 formed vertically and surrounded by a barrier layer 216 and an adhesive layer 214. The plurality of vias 218 are electrically isolated from each other by a dielectric layer 224. As shown, the dielectric layer 224 is deposited above the BEOL structure 204 and provides electrical isolation among the components included in the semiconductor die 200. Above each of the vias 218, a bond pad 210 is formed and electrically connected to corresponding probe pad 206 through the via 218. As shown in FIG. 2A, another dielectric layer 212 can be deposited above the dielectric layer 224 and provides electrical isolation between adjacent bond pads 210. Here, the dielectric layer 212 can be made of tetraethyl orthosilicate, silicon oxide, silicon nitride, silicon boron carbonitride, silicon oxycarbonitride, silicon oxycarbide, silicon carbonitride, silicon boronitride, a low-k dielectric material, or a combination thereof. In addition, the bond pads 210 can be made of electrically conductive materials such as copper, aluminum, gold, silver, nickel, platinum, palladium, tin, indium, titanium, or their alloys. Here, the bond pads 210 can be made of polycrystalline metal materials.

In this example, the bond pads 210 and the vias 218 can be fabricated using a dual damascene process. For example, the process can begin with the deposition of the dielectric layers 224 and 212. Then photolithography and etching processes can be conducted to create the patterns for vias and bond pad trenches. In this step, either via-first or trench-first approach can be adopted depending on preference of etching sequences. After forming the adhesive layer and barrier layer in the via trenches, conductive materials such as copper can be filled into the via and bond pad trenches to form a void-free fill with good electrical connectivity. Excess materials can be removed by a chemical mechanical polishing (CMP) process, which in turn planarizes the semiconductor die surface. As shown in FIG. 2A, the bond pads 210 may each has a diameter smaller than the corresponding via 218. For example, each of the bond pads 210 may have a diameter ranging from 50 nm to 5 μm, and a thickness ranging from 1 nm to 100 μm.

FIG. 2B illustrates a cross-sectional view of the semiconductor die 200 after forming a dielectric layer 220 above the dielectric layer 212 and bond pads 210. The dielectric layer 220 can be deposited using a physical vapor deposition (PVD) technique or a chemical vapor deposition (CVD) technique. In this example, the dielectric layer 220 can be made of materials including silicon nitride, silicon carbonitride, and silicon boron carbonitride, and a combination thereof. As shown in FIG. 2B, the dielectric layer 220 covers each of the bond pads 210 and is configured as a buffer layer to protect the bond pad material from damaging in downstream processes. Here, the dielectric layer 220 may have a thickness ranging from 1 nm to 1 μm.

In the next step, as shown in FIG. 2C, inert ions will be doped into the semiconductor die 200. For example, inert ions 226 can be implanted into the bond pads 210 through the dielectric layer 220. Here, an ion implantation process can be conducted for doping inert ions such as argon (Ar). Ion implantation process conditions including ion energy, ion dose, implantation angle, implantation temperature, and implantation time can be adjusted to achieve various doping levels of the inert ions at different maximum doping regions in the semiconductor die 200. For example, an Ar ion beam with a lower acceleration voltage and a higher dose level can be implanted into the bond pads 210 through its frontside surface to form a local maximum doping region that is deeper in the bond pad 210. In comparison, another Ar ion beam with a larger acceleration voltage and a lower dose level can be implanted into a shallower region of the bond pads 210. Here, the inert ions 226 may have a doping level in the bond pads 210 of the semiconductor die 200 ranging from 1×10¹⁵ ions-cm⁻² to 1×10²² ions-cm⁻². In this example, the inert ions 226 comprise materials including Ar ion, Helium ion, Neon ion, Krypton ion, and/or Xenon ion. In some other examples, silicon ions can also be doped into the bond pads 210. The acceleration voltage of the ion implantation process ranges from 1 KeV to 1 MeV. In this step, bond pad materials such as copper will not be damaged due to the ion implantation process as it is protected by the dielectric layer 220 which is disposed there above.

In some other examples, PVD process such as radio frequency (RF) sputtering process can be conducted to dope the inert ions 226 into the bond pads 210. For example, inert gas and a reactive gas such as Ar can be introduced into a vacuum chamber, and then the gases are ionized using a high energy source, creating a plasma. Positively charged inert ions 226 such as Ar ions can be then accelerated towards the frontside surface of the semiconductor die 200. The charged ions 226 can be then doped into the bond pads 210, through the dielectric layer 220. In some other examples, plasma doping (PLAD) process can be adopted for the ion doping into the bond pads 210. For example, a plasma containing desired doping species can be generated within a working chamber. Once the semiconductor die 200 is introduced into the working chamber, an electric field can be created by a bias voltage to accelerate the charged inert ions 226 towards the semiconductor die 200, wherein the inert ions are implanted into the bond pads 210 through the surface dielectric layer 220.

FIG. 2D illustrates a cross-sectional view of the semiconductor die 200 after the inert ions doping process. As shown, the inert ions can be disposed in the bond pads 210 as well as the dielectric layer 220. The inert ions can also be disposed in the dielectric layer 212. In this example, a peak doping level of the inert ions 226 in the semiconductor die 200 can be adjusted through controlling the processing parameters such as acceleration voltage and the inert ions dose level. Here, the peak doping level of the inert ions 226 is preferably disposed close to the top surfaces of the bond pads 210 to form random orientations of bond pad material thereon. In some other examples, the inert ions may be further transmitted down to the vias 218 and the dielectric layer 224.

In the present technology, the doped inert ions amorphizes at least a portion of the bond pads 210. For example, the amorphization may happen in a top portion of the bond pads 210 that is close to the dielectric layer 220. When high energy inert ions such as Ar ions penetrate the bond pads 210 such as copper, the Ar ion collide with copper items, transfer kinetic energy, and create collision cascades. The cascade can result in a displacement of copper atoms from its lattice sites, generating vacancies and interstitials defects. As the doping of inert ions continues, the density of defects in the bond pads 210 increased. When the defect density reaches a threshold value, the defects can no longer be accommodated by the crystal lattice (e.g., a face-centered cubic (FCC) crystal structure for copper), leading to formation of defect clusters and disordered regions/grains in the bond pad material. Bond pad material amorphization happens when the inert ions 226 causes a density of defects and disordered regions with which the original crystal lattice of bond pad material can not sustain its ordered structure. The amorphous region of the bond pad material expands as the doped inert ions dose increases. Here, a thickness of the amorphous region of the bond pad 210 ranges from 1 A to 5 μm.

In this example, the efficiency of amorphizing the bond pad 210 depends on the crystallographic orientation of the bond pad material. Certain orientations may be more susceptible to defect accumulation and amorphization due to differences in atomic packing density and the energy dissipation pathways available within the crystal structure. For example, bond pad 210 that is formed by FCC copper having a (111) orientation (e.g., {1111}planes) can act as efficient sinks for defects, which enables the recombination of vacancies and interstitials and limits the accumulation of defects.

FIG. 2D illustrates a cross-sectional view of the semiconductor die 200, specifically a protruded bond pad 230, after a thermal treatment process. In this example, the thermal treatment can be done by a rapid thermal processing (RTP) process or spike annealing process. For example, the semiconductor die 200 can be rapidly heated to the desired high temperature using powerful lamps or other radiant heating elements, such as tungsten-halogen lamps or arc lamps. The heating rate can be extremely high, reaching temperatures of up to 600° C. or more within a period up to 30 minutes. In the present technology, the thermal treatment process is employed to repair damages (i.e., amorphous bond pad regions) caused by the inert ions doping described earlier. It helps to repair the crystal lattice damage induced by ion implantation, restoring the crystalline structure of the bond pads 210. In addition, the recrystallization of the bond pad material causes the bond pad material to expand and protrude out of the bond pad trench. As shown in FIG. 2E, the protruded bond pad 230 is disposed above a frontside surface of the original bond pads 210 and the dielectric layer 212.

The expansion of the bond pad material (e.g., copper) volume may relate to several mechanisms associated with the defect recovery, recrystallization of amorphous bond pad material, and bond pad material grain growth phases. For example, the thermal annealing process involves heating the bond pad material, which inherently leads to thermal expansion due to increased atomic vibrations. The bond pad material expansion is a normal response to temperature increases and contributes to the overall volume change during the thermal treatment process. In another example, the amorphous bond pad material may be under internal stresses due to the disordered arrangement of atoms. As recrystallization occurs, during the thermal treatment process, these stresses can be released, potentially leading to changes in the bond pad material's volume as it seeks a lower energy state. In addition, gaps or voids may be formed close to the horizontal ends of each of the protruded bond pads 230, due to the deformation of dielectric layer 220 disposed above the corresponding bond pads 210.

As shown in FIG. 2E, the protruded bond pad 230 has a diameter larger than corresponding bond pad 210 disposed there below. For example, the protruded bond pad 230 may have a diameter that is 30% to 40% larger than the corresponding bond pad 210 along the top surface of the dielectric layer 212. In another example, the protruded bond pad 230 may have a volume that is about 40% to 50% of the corresponding bond pad 210. Here, the protruded bond pad 230 may have a thickness up to 1 μm and a diameter up to 10 μm. In this example, the protruded bond pads 230 have a higher degree of crystallinity in comparison to the bond pads 210. Specifically, the protruded bond pads 230 may have a lower resistivity in comparison to the as deposited bond pad material. For example, the bond pads 210 and protruded bond pads 230 can be made of copper. The bond pads 210 may have a resistivity close to or higher than 1.7×10⁻⁸ Ω·m at room temperature. In contrast, the protruded bond pads 230 may have a resistivity close to or lower than 1.7×10⁻⁸ Ω·m at room temperature, due to its higher degree of crystallinity.

In a next step, the dielectric layer 220 can be removed from the semiconductor die 200. Here, a dry etching process or a wets chemistry etching process can be adopted to selectively remove the dielectric layer 220 without damaging the protruded bond pads 230 and dielectric layer 212. For example, a phosphoric acid (H₃PO₄) etching process can be adopted to remove the dielectric layer 220 (e.g., a SiN layer) selective to the underneath protruded bond pad (e.g., copper) and dielectric layer 212 (e.g., SiO₂ layer). FIG. 2F illustrate a cross section view of the semiconductor die 200 after the dielectric layer 220 removal process. As shown, the protruded bond pads 230 are disposed, in a mushroom shape, above the frontside surface of the semiconductor die 200.

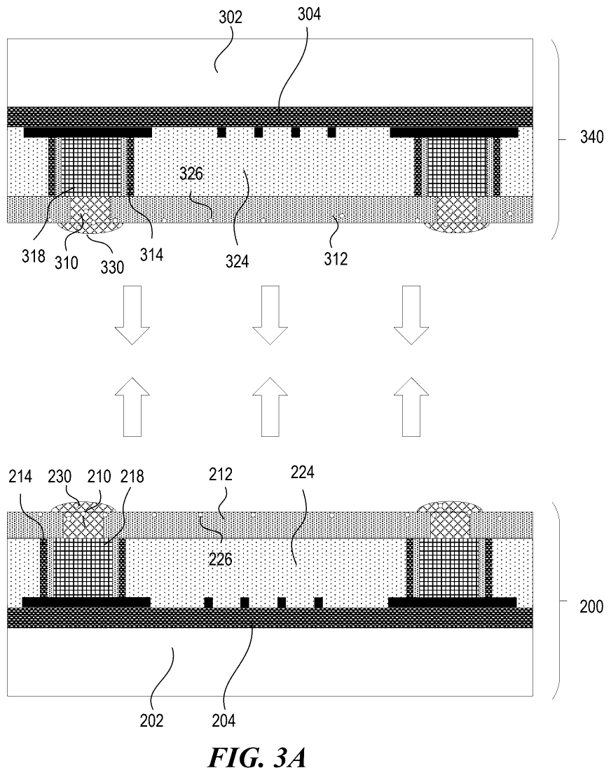

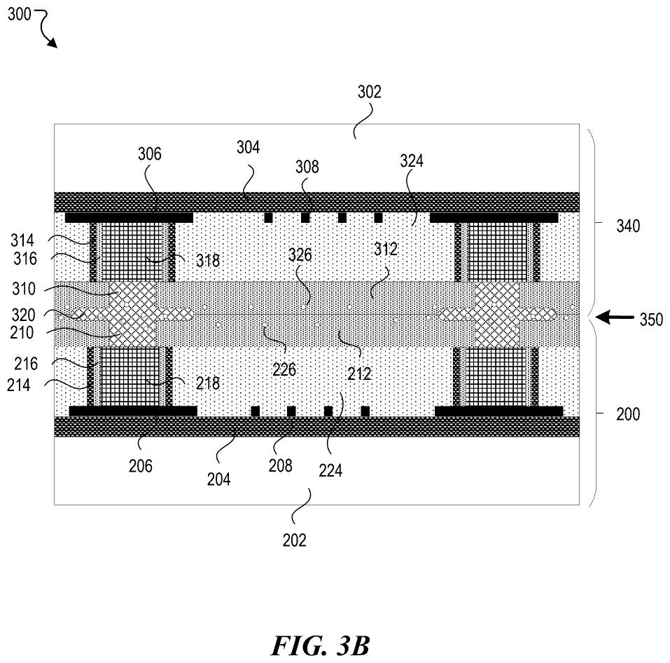

FIGS. 3A and 3B illustrate stages of hybrid bonding two semiconductor dies having protruded conductive regions in accordance with embodiments of the present technology. As shown, the top semiconductor die 340 includes a dielectric layer 312, bond pads 310 and protruded bond pad 330. In addition, the top semiconductor die 340 is flipped upside down and bonded towards the bottom semiconductor die 200 by aligning the bond pads 310 to the bond pads 210 and applying a compression pressure. In this example, the top semiconductor die 340 can be manufactured using processes similar to the ones described in FIGS. 2A to 2F. Further, the top semiconductor die 340 can be identical to the semiconductor die 200.

FIG. 3B illustrates a semiconductor device assembly 300 that contains the semiconductor dies 200 and 300. In particular, the semiconductor device assembly 300 contains a hybrid bonding at the bonding interface 350, which includes dielectric-dielectric bonds between the dielectric layer 312 of the top semiconductor die 340 and the dielectric layer 212 of the bottom semiconductor die 200. This hybrid bonding also includes metal-metal bonds between the bond pads 210, conductive regions 320, and bond pads 310. In this example, the bond pads 210 and 320, as well as the conductive regions 320 can be made of a same conductive material element such as copper.

In some examples, the dielectric-dielectric bonds between the dielectric layers 312 and 212 can be strong covalent bonds, e.g., SiO—SiO bonds or SiN—SiN bonds, without any gaps nor voids. Further, the dielectric layers 312 and 212 can be fused together by applying heat and/or compression force to the semiconductor device assembly 300. For example, the semiconductor device assembly 300 can go through another thermal anneal process close to 150° C. for about 4 hours to facilitate forming the dielectric-dielectric covalent bonds between the dielectric layers 312 and 212.

In some examples, the metal-metal bonds of the hybrid bonding process described in FIG. 3A are formed by contacting the protruded bond pads 330 and 230. Once the protruded bond pads 330 and 230 are aligned, the semiconductor dies 200 and 300 can be brought into contact, and the metal-metal bonds is achieved through a combination of an elevated temperature, pressure, and/or ultrasonic energy. For example, a copper to copper bonding can be formed at a temperature lower than melting point of the copper to enable diffusion bonding between the protruded bond pads 330 and 230, without melting the bond pad material. Here, the metal-metal bonds are formed within the conductive regions 320 without any gaps or voids.

As shown in FIG. 3B, the conductive regions 320 are formed by compressing corresponding protruded bond pads 330 and 230 in the vertical direction. As a result, each of the conductive regions 320 is elongated along the bonding interface 350 and has a larger diameter to the protruded bond pads 230 and 330. Here, each of the conductive regions 320 may have a diameter ranging from 70 nm to 20 μm and a thickness ranging from 1 A to 5 μm. In this example, the dimensions of the conductive regions 320 shown in FIG. 3B are for illustrative purposes only, e.g., its diameter can be much larger than that of the corresponding bond pads 210 or vias 218. Further, in the semiconductor device assembly 300, inert ions 226 and 326 are disposed close to the bonding interface 350, e.g., within the conductive regions 320, the bond pads 210 and 310, and the dielectric layers 212 and 312.

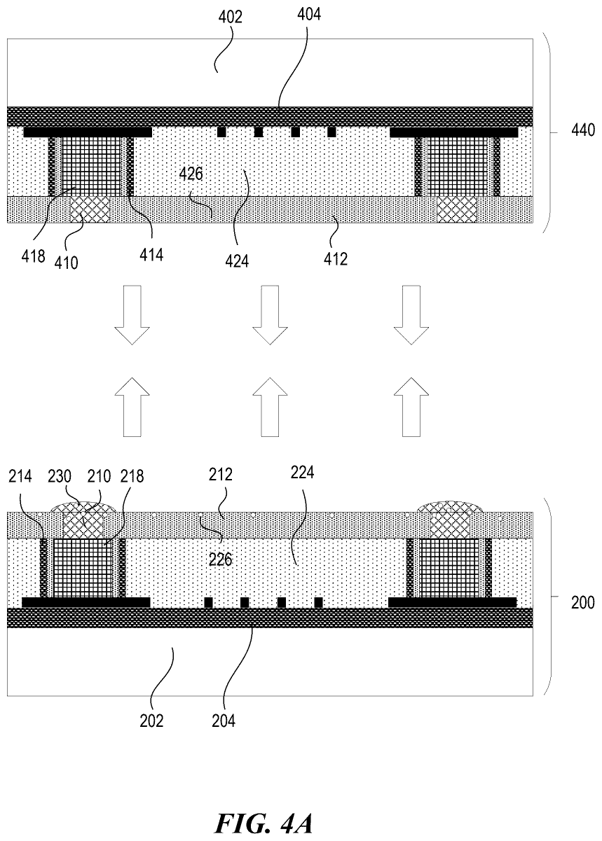

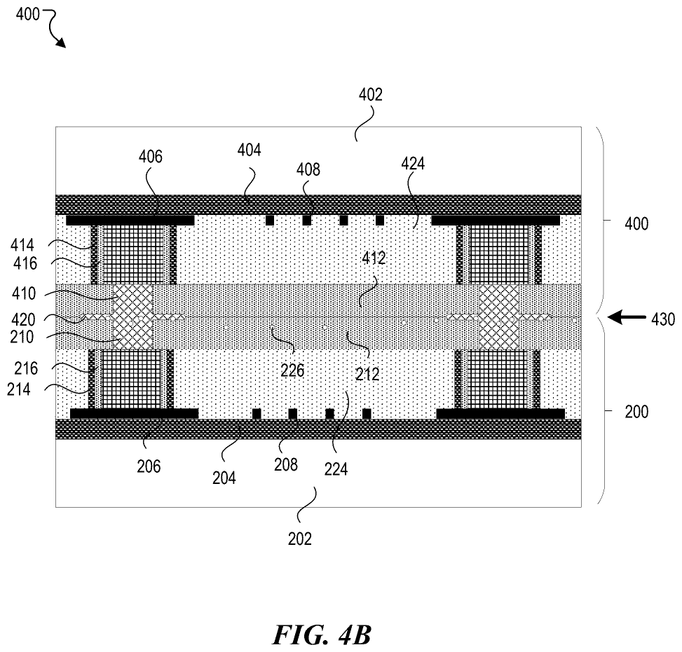

FIGS. 4A and 4B illustrate stages of hybrid bonding of semiconductor device assembly 400 with and without protruded conductive regions, in accordance with embodiments of the present technology. As shown in FIG. 4A, the top semiconductor die 440 includes a dielectric layer 412, and bond pads 410. In addition, the top semiconductor die 440 is flipped upside down and towards the bottom semiconductor die 200 by aligning the bond pads 410 to the bond pads 210 and applying a compression pressure. In this example, the top semiconductor die 340 can be manufactured similar to the process steps described in FIG. 2A. Further, the bottom semiconductor die 200 includes bond pads 210, protruded bond pads 230 and dielectric layer 212.

As shown in FIG. 4B, the semiconductor die 440 can be bonded to the semiconductor die 200 through hybrid bonding process and along a bonding interface 430. In this example, conductive regions 420 are formed by compressing corresponding protruded bond pads 230 and bond pads 410 in the vertical direction. As a result, each of the conductive regions 420 is elongated along the bonding interface 430 and has a larger diameter to the protruded bond pads 230. Here, each of the conductive regions 420 may have a diameter ranging from 70 nm to 10 μm and a thickness ranging from 1 A to 3 μm. In some examples, the dielectric-dielectric bonds between the dielectric layers 212 and 412 can be strong covalent bonds, e.g., SiO—SiO bonds or SiN—SiN bonds, without any gaps nor voids. In addition, the metal-metal bonds can be formed between the protruded bond pad 230 and corresponding bond pads 410. Electrical and power signals can be transmitted between the semiconductor dies 200 and 440 through the bond pads 210, conductive regions 420, and corresponding bond pads 410. In this example, the inert ions 226 are disposed in the semiconductor die 200, e.g., within the conductive regions 420, the bond pads 210, and the dielectric layer 212.

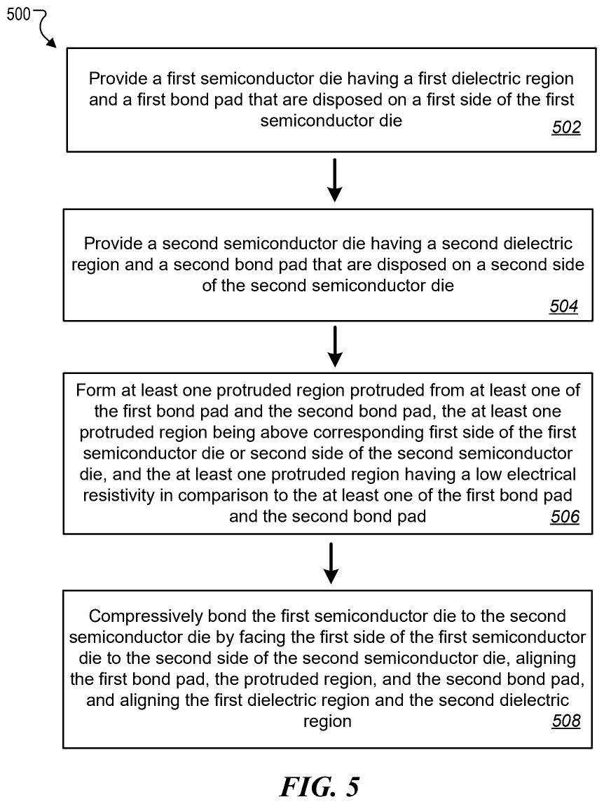

FIG. 5 is a flow chart illustrating a method 500 of processing semiconductor device assemblies according to embodiments of the present technology. The method 500 includes providing a first semiconductor die having a first dielectric region and a first bond pad that are disposed on a first side of the first semiconductor die, at 502. For example, the semiconductor die 200 can be provided for the semiconductor die assembly. As shown in FIG. 3A, the semiconductor die 200 includes the dielectric layer 212 and the bond pads 210.

The method 500 also includes providing a second semiconductor die having a second dielectric region and a second bond pad that are disposed on a second side of the second semiconductor die, at 504. For example, the semiconductor die assembly 300 can be provided for the semiconductor die assembly. As shown in FIG. 3A, the semiconductor die assembly 300 includes the dielectric layer 312 and the bond pads 310. The semiconductor die assembly 300 can be identical to the semiconductor die 200 for the hybrid bonding process.

In addition, the method 500 includes forming at least one protruded region protruded from at least one of the first bond pad and the second bond pad, the at least one protruded region being above corresponding first side of the first semiconductor die or second side of the second semiconductor die, and the at least one protruded region having a low electrical resistivity in comparison to the at least one of the first bond pad and the second bond pad, at 506. For example, the protruded bond pads 230 can be formed on the semiconductor die 200. In particular, the protruded bond pads 230 can be formed above the frontside surface of the semiconductor die 200 and above corresponding bond pads 210. Similarly, the protruded bond pads 330 can be formed on the semiconductor die assembly 300. In particular, the protruded bond pads 330 can be formed above the frontside surface of the semiconductor die assembly 300 and above corresponding bond pads 310.

Lastly, the method 500 includes compressively bonding the first semiconductor die to the second semiconductor die by facing the first side of the first semiconductor die to the second side of the second semiconductor die, aligning the first bond pad, the protruded region, and the second bond pad, and aligning the first dielectric region and the second dielectric region, at 508. For example, the semiconductor die 200 and the semiconductor die assembly 300 can be bonded face to face during a hybrid bonding process. The hybrid bonding interface 350 is formed by aligning the bond pads 210, the protruded bond pad 230, and the bond pads 310, and by aligning the dielectric layers 212 and 312. In this example, the dielectric-dielectric bonds are formed between the dielectric layers 212 and 312. Metal-metal bonds are formed between the bond pads 210 and corresponding bond pads 310, as shown in FIG. 3B. Particularly, the metal-metal bonds are disposed within conductive regions 320 of bonding interface 350 of the semiconductor die assembly 300.

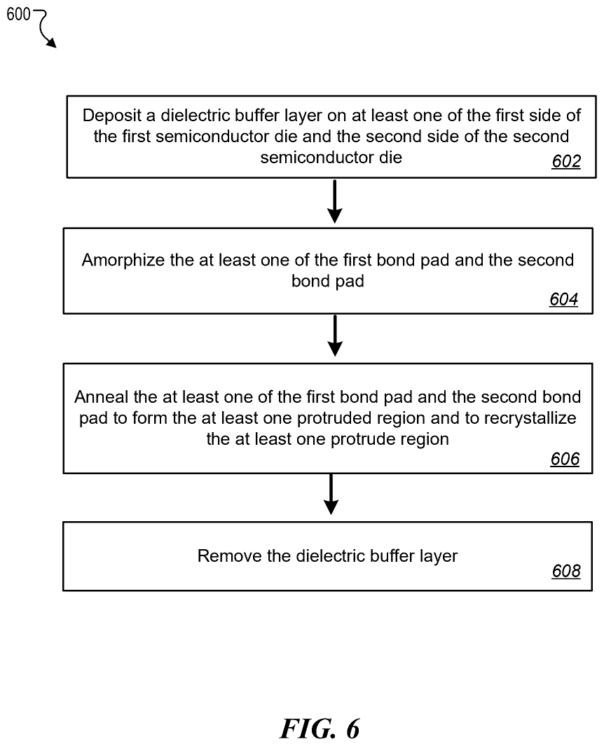

FIG. 6 is a flow chart illustrating a method 600 of forming protruded conductive regions above a frontside surface of a semiconductor die according to embodiments of the present technology. The method 600 includes depositing a dielectric buffer layer on at least one of the first side of the first semiconductor die and the second side of the second semiconductor die, at 602. For example, a dielectric layer 220 can be deposited on a frontside surface of the semiconductor die 200. As shown in FIG. 2B, a SiN layer 220 can be formed above the dielectric layer 212 and bond pads 210 of the semiconductor die 200.

In addition, the method 600 includes amorphizing the at least one of the first bond pad and the second bond pad, at 604. For example, once the dielectric layer 220 is formed to cover the bond pads 210, inert ions 226 can be implanted into the semiconductor die 200. For example, as shown in FIGS. 2C and 2D, Ar ions can be implanted, using an ion implantation process, into the bond pads 210 and dielectric layers 212 through the dielectric layer 220. The implanted inert ions 226 degrades the bond pad material crystallinity, introduces defects, and amorphizes the bond pad material.

Further, the method 600 includes annealing the at least one of the first bond pad and the second bond pad to form the at least one protruded region and to recrystallize the at least one protrude region, the recrystallized at least one protrude region having an electrical resistivity lower than the at least one of the first bond pad and the second bond pad, at 606. For example, a thermal treatment process such as RTP anneal or spike anneal can be conducted on the semiconductor die 200, specifically on the amorphous regions of bond pads 210, to form the protruded bond pads 230. As shown in FIG. 2E, the protruded bond pads 230 is disposed above the dielectric layer 212 and in a mushroom shape. In addition, the protruded bond pads 230 have a high degree of crystallinity, which leads to a lower electrical resistivity in comparison to the bond pads 230.

Lastly, the method 600 includes removing the dielectric buffer layer, at 608. For example, once the protruded bond pads 230 are formed, the dielectric layer 220 can be removed by a selective dry etch process or a selective wets etch process, as illustrated in FIG. 2F.

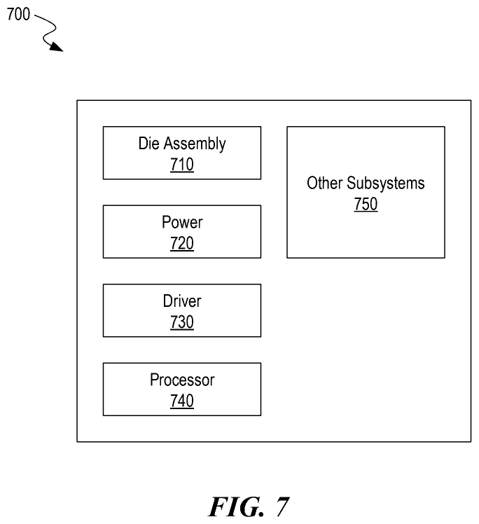

Any one of the semiconductor structures described above with reference to FIGS. 1-4B can be incorporated into any of a myriad of larger and/or more complex systems, a representative example of which is system 700 shown schematically in FIG. 7. The system 700 can include a semiconductor die assembly 710, a power source 720, a driver 730, a processor 740, and/or other subsystems or components 750. The semiconductor die assembly 710 can include features generally similar to those of the semiconductor devices described above, and can therefore include the conductive regions formed at hybrid bonding interface described in the present technology. The resulting system 700 can perform any of a wide variety of functions, such as memory storage, data processing, and/or other suitable functions. Accordingly, representative systems 700 can include, without limitation, hand-held devices (e.g., mobile phones, tablets, digital readers, and digital audio players), computers, and appliances. Components of the system 700 may be housed in a single unit or distributed over multiple, interconnected units (e.g., through a communications network). The components of the system 700 can also include remote devices and any of a wide variety of computer-readable media.

Specific details of several embodiments of semiconductor devices, and associated systems and methods, are described below. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

In accordance with one aspect of the present technology, the semiconductor device assembly described above could include a semiconductor memory device and a logic interface wafer. The semiconductor device assembly may further include one or more high-temperature (HT) processed dielectric layers (e.g., HT SiCN, HT SiO, and/or HT SiN) and one or more bond pads (e.g., Cu—Cu pads) that are sandwiched between the semiconductor memory device and the logic interface wafer. The HT processed dielectric layers and the bond pads can be formed at temperatures close to or above 300° C.

In accordance with another aspect of the present technology, the semiconductor device assembly described above could include a semiconductor memory device and a logic interface wafer having a backside surface. The backside surface of the logic interface wafer may include one or more HT processed dielectric layers (e.g., HT SiCN, HT SiO, and/or HT SiN). Specifically, the semiconductor memory device and the logic interface wafer are coupled/bonded through various bond pads (e.g., Cu—Cu pads).

In accordance with one aspect of the present disclosure, the semiconductor devices illustrated above could be memory dice, such as dynamic random access memory (DRAM) dice, NOT-AND (NAND) memory dice, NOT-OR (NOR) memory dice, magnetic random access memory (MRAM) dice, phase change memory (PCM) dice, ferroelectric random access memory (FeRAM) dice, static random access memory (SRAM) dice, or the like. In an embodiment in which multiple dice are provided in a single assembly, the semiconductor devices could be memory dice of a same kind (e.g., both NAND, both DRAM, etc.) or memory dice of different kinds (e.g., one DRAM and one NAND, etc.). In accordance with another aspect of the present disclosure, the semiconductor dice of the assemblies illustrated and described above could be logic dice (e.g., controller dice, processor dice, etc.), or a mix of logic and memory dice (e.g., a memory controller die and a memory die controlled thereby).

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “top,” “bottom,” “over,” “under,” “above,” and “below” can refer to relative directions or positions of features in the semiconductor devices in view of the orientation shown in the Figures. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a first semiconductor die having a first dielectric region and a first bond pad that are disposed on a first side of the first semiconductor die; and
a second semiconductor die having a second dielectric region and a second bond pad that are disposed on a second side of the second semiconductor die,
wherein a hybrid bonding interface between the first side of the first semiconductor die and the second side of the second semiconductor die includes a conductive region between the first bond pad and the second bond pad, and
wherein the conductive region and at least one of the first and the second bond pads include a same conductive material element, and the conductive region has an electrical resistivity lower than the at least one of the first and the second bond pads.

2. The semiconductor device assembly of claim 1, wherein the same conductive material element comprises copper, aluminum, gold, silver, nickel, platinum, palladium, tin, indium, titanium, or their alloys.

3. The semiconductor device assembly of claim 1, wherein the conductive region has a larger averaged grain size and a lower density of grain boundaries than the at least one of the first bond pad and the second bond pad.

4. The semiconductor device assembly of claim 1, wherein the conductive material of the conductive region is polycrystalline.

5. The semiconductor device assembly of claim 1, further comprises inert ions in the conductive region.

6. The semiconductor device assembly of claim 5, wherein the inert ions are disposed in at least one of the first dielectric region and the second dielectric region.

7. The semiconductor device assembly of claim 5, wherein the inert ions are disposed in the at least one of the first bond pad and the second bond pad.

8. The semiconductor device assembly of claim 5, wherein the inert ions comprise Ar ion, Helium ion, Neon ion, Krypton ion, and/or Xenon ion.

9. The semiconductor device assembly of claim 1, wherein the conductive region is larger than the at least one of the first bond pad or the second bond pad along the hybrid bonding interface.

10. The semiconductor device assembly of claim 9, wherein the conductive region has a volume up to 50% of the at least one of the first bond pad or the second bond pad.

11. The semiconductor device assembly of claim 1, wherein the hybrid bonding interface includes a dielectric-dielectric bonding region between the first and the second dielectric regions.

12. The semiconductor device assembly of claim 1, wherein the first dielectric region and the second dielectric region comprise silicon oxide, silicon nitride, silicon carbon nitride, or a combination thereof.

13. A semiconductor device assembly, comprising:
a first semiconductor die having a first dielectric region and a first bond pad that are disposed on a first side of the first semiconductor die; and
a second semiconductor die having a second dielectric region and a second bond pad that are disposed on a second side of the second semiconductor die,
wherein a hybrid bonding interface between the first side of the first semiconductor die and the second side of the second semiconductor die includes a conductive region connected to the first bond pad and the second bond pad, and
wherein inert ions are disposed in the conductive region and at least one of the first bond pad and the second bond pad.

14. The semiconductor device assembly of claim 13, wherein the inert ions are disposed in at least one of the first dielectric region and the second dielectric region.

15. The semiconductor device assembly of claim 13, wherein the inert ions comprise Ar ion, Helium ion, Neon ion, Krypton ion, and/or Xenon ion.

16. The semiconductor device assembly of claim 13, wherein the conductive region has an electrical resistivity lower than the at least one of the first bond pad and the second bond pad.

17. A method of forming a semiconductor device assembly, comprising:
providing a first semiconductor die having a first dielectric region and a first bond pad that are disposed on a first side of the first semiconductor die;
providing a second semiconductor die having a second dielectric region and a second bond pad that are disposed on a second side of the second semiconductor die;
forming at least one protruded region protruded from at least one of the first bond pad and the second bond pad, the at least one protruded region being above corresponding first side of the first semiconductor die or the second side of the second semiconductor die, and the at least one protruded region having a low electrical resistivity in comparison to the at least one of the first bond pad and the second bond pad; and
compressively bonding the first semiconductor die to the second semiconductor die by facing the first side of the first semiconductor die to the second side of the second semiconductor die, aligning the first bond pad, the protruded region, and the second bond pad, and aligning the first dielectric region and the second dielectric region.

18. The method of forming the semiconductor device assembly of claim 17, wherein forming the at least one protruded region includes:
depositing a dielectric buffer layer on at least one of the first side of the first semiconductor die and the second side of the second semiconductor die,
amorphizing the at least one of the first bond pad and the second bond pad,
annealing the at least one of the first bond pad and the second bond pad to form the at least one protruded region and to recrystallize the at least one protrude region, the recrystallized at least one protrude region having an electrical resistivity lower than the at least one of the first bond pad and the second bond pad and
removing the dielectric buffer layer.

19. The method of forming the semiconductor device assembly of claim 18, wherein amorphizing the at least one of the first bond pad and the second bond pad includes:
implanting inert ions into the at least one of the first bond pad and the second bond pad, or
sputtering the inert ions into the at least one of the first bond pad and the second bond pad.

20. The method of forming the semiconductor device assembly of claim 18, wherein annealing the at least one protruded region includes annealing the at least one protruded region at a temperature ranging from 300° C. to 600° C. and for a period up to 30 minutes.
